(19) United States
(12) Patent Application Publication
(10) Pub. No.: US 2026/0333783 A1
(43) Pub. Date: Oct. 22, 2026

(54) SEMICONDUCTOR DEVICE AND METHOD OF MANUFACTURING THE SAME

(71) Applicant: WUHAN XINXIN SEMICONDUCTOR MANUFACTURING CO., LTD., Wuhan (CN)

(72) Inventors: Ruizhang XU, Wuhan (CN); Zhaojin SUN, Wuhan (CN); Enying XING, Wuhan (CN); Qiming QU, Wuhan (CN); Qiong WANG, Wuhan (CN); Nian LIU, Wuhan (CN); Dong PAN, Wuhan (CN)

(21) Appl. No.: 19/401,324

(22) Filed: Nov. 25, 2025

(30) Foreign Application Priority Data
Nov. 29, 2024 (CN) 202411748238.2

(51) Int. Cl. H10D 62/10; H10D 30/01; H10D 30/60; H10D 64/27; H10W 10/17

(52) U.S. Cl. CPC H10D 62/102; H10D 30/023; H10D 30/611; H10D 64/519; H10W 10/17

(57) ABSTRACT

The present disclosure provides a semiconductor device and a method of manufacturing it. The semiconductor device includes: a substrate defining an active area; an isolation layer formed in the substrate in the active area; and a gate layer formed over the substrate in the active area. The gate layer includes main gate and the extended gate, which are separated apart from each other, and projections of which on the substrate are bridged by the isolation layer. The present disclosure ensures that the gate layer functions as desired while avoiding the semiconductor device from any degradation in performance due to parasitic capacitance.

### CROSS-REFERENCES TO RELATED APPLICATIONS

This application claims the priority of Chinese patent application number 202411748238.2, filed on Nov. 29, 2024, the entire contents of which are incorporated herein by reference.

### TECHNICAL FIELD

The present disclosure relates to the field of semiconductor integrated circuit manufacturing technology, and particularly to a semiconductor device and a method of manufacturing it.

### BACKGROUND

In semiconductor devices, body contacts are commonly provided by body-tied-to-source (BTS), T-gate, H-gate and like structures. For example, FIG. 1 shows a device employing a T-gate structure. As can be seen from FIG. 1, a T-gate layer 11 is formed on a substrate. A source region 12 and a drain region 13 are formed in the substrate on opposite sides of a vertical arm of the T-gate layer 11. A body contact region 14 is formed in the substrate on the side of a horizontal arm of the T-gate layer 11 away from the source region 12 and the drain region 13. During the fabrication of a device with the T-gate structure of FIG. 1, a border AA′ of an ion-implanted region A1 for the source region 12 and the drain region 13 and an ion-implanted region A2 for the body contact region 14 must reside on the horizontal arm of the T-gate layer 11. Otherwise, the extents of the resulting source region 12, drain region 13 and body contact region 14 may be adversely affected, leading to degraded performance of the device.

Limited by the critical dimensions (CDs) of the processes used to form the gate layer 11, the source region 12, the drain region 13 and the body contact region 14 and variations in alignment accuracy of the photomasks used, a gate length L1 of the horizontal arm of the gate layer 11 measured in the direction from the source region 12 to the body contact region 14 should not be made too small (e.g., not less than 0.3μm). On the other hand, an excess of this gate length L1 may lead to increased parasitic capacitance, which is detrimental to the performance of the resulting device.

Therefore, how to enable the gate layer to function as desired while avoiding parasitic capacitance induced degradation of the device's performance remains a problem requiring urgent attention.

### SUMMARY

It is an object of the present disclosure to provide a semiconductor device and a method of manufacturing the device, which allows a gate layer in the device to function as desired while avoiding parasitic capacitance induced performance degradation of the device.

To this end, the present disclosure provides a semiconductor device including:
a substrate defining an active area;
an isolation layer formed in the substrate in the active area; and
a gate layer formed over the substrate in the active area, the gate layer including a main gate and an extended gate, which are separated apart from each other, and projections of which on the substrate are bridged by the isolation layer.

The present disclosure also provides a method of manufacturing a semiconductor device, which includes:
providing a substrate defining an active area;
forming an isolation layer in the substrate in the active area; and
forming a gate layer over the substrate in the active area, the gate layer including a main gate and an extended gate, which are separated apart from each other, and projections of which on the substrate are bridged by the isolation layer.

The present disclosure provides the following benefits over the prior art:
1. It provides a semiconductor device including: a substrate defining an active area; an isolation layer formed in the substrate in the active area; and a gate layer formed over the substrate in the active area. The gate layer includes main gate and the extended gate, which are separated apart from each other, and projections of which on the substrate are bridged by the isolation layer. With this arrangement, it can be ensured that the gate layer functions as desired while avoiding the semiconductor device from any degradation in performance due to parasitic capacitance. Moreover, since the isolation layer is formed in the substrate, accurate control is unnecessary, simplifying the manufacturing process.
2. It provides a method of manufacturing a semiconductor device, which includes: forming an isolation layer in a substrate in active area defined thereby; and forming a gate layer over the substrate in the active area. The gate layer includes main gate and the extended gate, which are separated apart from each other, and projections of which on the substrate are bridged by the isolation layer. In this way, it can be ensured that the gate layer functions as desired while avoiding the resulting semiconductor device from any degradation in performance due to parasitic capacitance. Moreover, since the isolation layer is formed in the substrate, accurate control is unnecessary, simplifying the manufacturing process.

### BRIEF DESCRIPTION OF THE DRAWINGS

FIG. 1 is a schematic top view of a device with a T-gate structure.

FIG. 2a is a schematic illustration of a semiconductor device according to a first embodiment of the present disclosure.

FIG. 2b is a schematic cross-sectional view of the semiconductor device of FIG. 2a taken along line BB′.

FIG. 3 is a schematic illustration of a semiconductor device according to a second embodiment of the present disclosure.

FIG. 4 is a schematic illustration of a semiconductor device according to a third embodiment of the present disclosure.

FIG. 5 is a schematic illustration of a semiconductor device according to a fourth embodiment of the present disclosure.

FIG. 6 shows a flowchart of a method of manufacturing a semiconductor device according to an embodiment of the present disclosure.

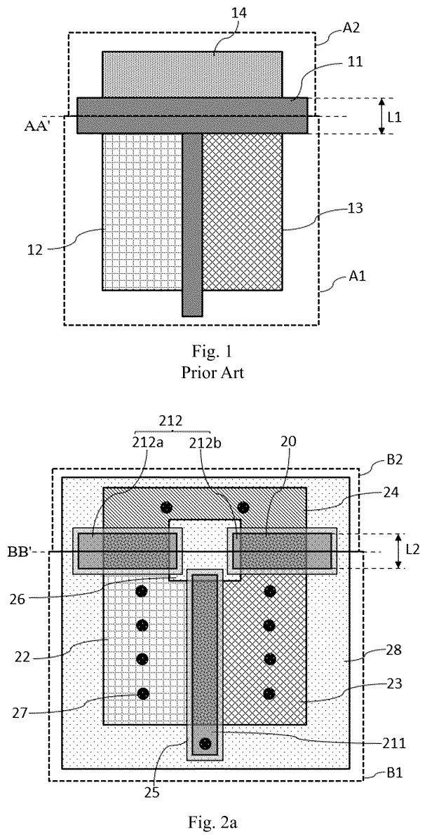

In FIGS. 1 to 6,
11 denotes a gate layer; 12, a source region; 13, a drain region; 14, a body contact region; 20, a substrate; 201, a gate dielectric layer; 211, a main gate; 212, an extended gate; 212a, a first portion; 212b, a second portion; 22, a source region; 23, a drain region; 24, a body contact region; 25, a spacer; 26, an isolation layer; 27, a conductive plug; and 28, a STI structure.

### DETAILED DESCRIPTION

Objects, features and advantages of the present disclosure will become more apparent upon reading the following detailed description of semiconductor devices and fabrication methods proposed herein. Note that the figures are provided in a very simplified form not necessarily drawn to exact scale for the only purpose of helping to explain the disclosed embodiments in a more convenient and clearer way.

In one embodiment of the present disclosure, there is provided a semiconductor device including: a substrate defining an active area; an isolation layer formed in the substrate in the active area; and a gate layer formed over the substrate in the active area. The gate layer includes main gate and the extended gate, which are separated apart from each other, and projections of which on the substrate are bridged by the isolation layer.

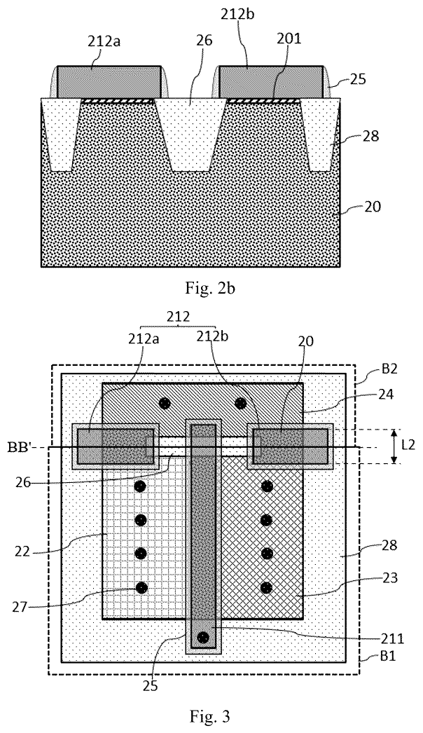

The semiconductor device of this embodiment is described in detail below with reference to FIGS. 2a to 5. FIGS. 2a, 3, 4 and 5 are schematic top views of the semiconductor device.

The substrate 20 may be either a single-layer structure, or a multi-layer structure consisting of multiple layers of the same or different materials. Without limitation, examples of the material of the substrate 20 may include semiconductor materials, such as Si, SiGe, SiGeC, SiC, GaAs, InAs, InP and other III/V or II/VI compound semiconductors, or the substrate 20 may be a layered substrate, such as Si/SiGe, Si/SiC, silicon on insulator (SOI) or silicon germanium on insulator (SiGeOI).

The substrate 20 defines an active area.

The semiconductor device further includes a shallow trench isolation (STI) structure 28, which is formed in the substrate 20 so as to delimit the active area.

The isolation layer 26 is formed in the substrate 20 in the active area.

Preferably, the isolation layer 26 and the STI structure 28 are formed of the same material in a single process. That is, during the formation of the STI structure 28 in the substrate 20, the isolation layer 26 is formed in the substrate 20 surrounded by the STI structure 28. This can simplify the manufacturing process and reduce the manufacturing cost. In other embodiments, the isolation layer 26 and the STI structure 28 may be formed in different processes.

The isolation layer 26 and the STI structure 28 may each be made of at least one of silicon oxide, silicon nitride and silicon oxynitride.

Preferably, the top surfaces of the STI structure 28 and the isolation layer 26 are not lower than a top surface of the substrate 20. In other embodiments, the top surfaces of the STI structure 28 and the isolation layer 26 may be slightly lower than the top surface of the substrate 20.

The gate layer is formed over the substrate in the active area 20 and includes a main gate 211 and an extended gate 212, which are separated apart from each other. That is, the main gate 211 and the extended gate 212 are spaced apart by a gap, and not electrically connected to, each other.

A gate dielectric layer 201 is formed between the gate layer and the substrate 20. The gate layer, the gate dielectric layer 201 and the substrate 20 make up a capacitor structure.

The gate dielectric layer 201 may be made of silicon oxide (with a relative permittivity of 4.1) or another dielectric material. Constructing the gate dielectric layer with a low-permittivity (low-k) material can reduce the capacitance.

A spacer 25 is formed on sidewalls of the main gate 211 and the extended gate 212.

Projections of the main gate 211 and the extended gate 212 on the substrate 20 are bridged by the isolation layer 26.

The projections of the main gate 211 and the extended gate 212 on the substrate 20 may overlap the isolation layer 26. That is, borders of the projections of the main gate 211 and the extended gate 212 on the substrate 20 may coincide with borders of the isolation layer 26. In another embodiment, the projections of the main gate 211 and the extended gate 212 on the substrate 20 may extend on portions of the isolation layer 26. With this arrangement, accurate alignment with the borders of the isolation layer 26 is unnecessary during the formation of the main gate 211 and the extended gate 212, enabling easier process control.

Through bridging the projections of the main gate 211 and the extended gate 212 on the substrate 20 with the isolation layer 26, during subsequent formation of a source region 22, a drain region 23 and a body contact region 24 by implanting ions into the active area, the main gate 211, the extended gate 212 and the bridging isolation layer 26 can together serve as a barrier to prevent connection of the source region 22 and the drain region 23 to each other, or connection of the source region 22 or the drain region 23 to the body contact region 24, which may lead to a short circuit.

The semiconductor device further includes:
a source region 22 and a drain region 23, which are formed both in the active area on opposite sides of the main gate 211, or of the main gate 211 and the isolation layer 26, wherein a region under the main gate 211 between the source region 22 and the drain region 23 provides a channel region;
a body contact region 24 formed in the active area on the side of the extended gate 212 and the isolation layer 26 away from the main gate 211.

The body contact region 24 is formed to connect the substrate 20 under the channel region (i.e., a body region). The STI structure 28 surrounds the source region 22, the drain region 23 and the body contact region 24.

In one embodiment, the source region 22 and the drain region 23 may extend to the substrate 20 under the spacer 25. The body contact region 24 may also extend to the substrate 20 under the spacer 25.

The source region 22 and the drain region 23 are of the same doping type. The body contact region 24 and the source region 22 can have different doping type. When the doping types of the body contact region 24 and the source region 22 are opposite, the semiconductor device is an enhancement-mode field effect transistor.

In case of the body contact region 24 and the source region 22 being of opposite doping types, if the source region 22 and the drain region 23 are n-type regions, then the body contact region 24 is a p-type region. On the contrary, if the source region 22 and the drain region 23 are p-type regions, then the body contact region 24 is an n-type region.

As shown in FIGS. 2a, 3 and 4, the main gate 211 and the extended gate 212 may make up a T-shaped structure, together with the isolation layer 26 that bridges their projections on the substrate 20. In this case, the main gate 211 provides a vertical arm of the T-shaped structure, and the extended gate 212 provides a horizontal arm of the T-shaped structure. Alternatively, as shown in FIG. 5, the main gate 211 and the extended gate 212 may make up an H-shaped structure, together with the isolation layer 26 that bridges their projections on the substrate 20. In this case, the main gate 211 provides a horizontal arm of the H-shaped structure, and the extended gate 212 provides vertical arms of the H-shaped structure.

As long as the isolation layer 26 bridges the projections of the separated main gate and the extended gate 211, 212 on the substrate 20, the present disclosure is not limited to any particular arrangement that accomplishes the bridging. For example, the shapes and dimensions of the isolation layer 26, the main gate 211 and the extended gate 212 may vary depending on the actual processes used.

In one embodiment, as shown in FIGS. 2a, 3 and 5, the extended gate 212 may include a first portion 212a and a second portion 212b, which are separated apart from each other, and projections of the first portion 212a and the second portion 212b on the substrate 20 are bridged by the isolation layer 26. The projection of the main gate 211 on the substrate 20 may extend from the active area on one side of the isolation layer 26 at least to the isolation layer 26. As shown in FIGS. 2a and 5, the projection of the main gate 211 on the substrate 20 may extend from the active area on one side of the isolation layer 26 just to the isolation layer 26. In this case, the source region 22 and the drain region 23 are formed in the active area on opposite sides of the main gate 211 and the isolation layer 26, and the body contact region 24 is formed in the active area on the side of the extended gate 212 and the isolation layer 26 away from the main gate 211. Alternatively, as shown in FIG. 3, the projection of the main gate 211 on the substrate 20 may extend from the active area on one side of the isolation layer 26 across the entire isolation layer 26 to the active area on the other side of the isolation layer 26. In this case, the source region 22 and the drain region 23 are formed in the active area on opposite sides of the main gate 211, and the body contact region 24 is formed in the active area on the side of the extended gate 212 and the isolation layer 26 away from the source region 22 and the drain region 23. The latter case provides a higher degree of process controllability.

It should be noted that a gate length L2 of the extended gate 212 measured in a direction from the source region 22 to the body contact region 24 does nothing with a length of the isolation layer 26 measured in the same direction.

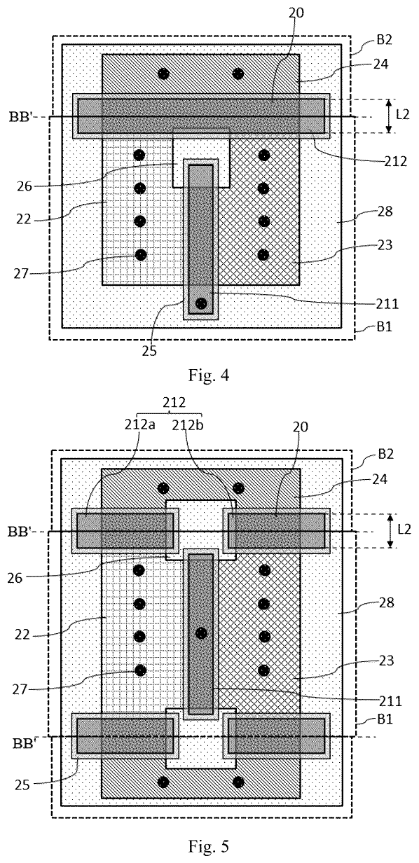

In an alternative embodiment, as shown in FIG. 4, the extended gate 212 is provided as a single unitary piece. In this case, the source region 22 and the drain region 23 are formed in the active area on opposite sides of the main gate 211 and the isolation layer 26, and the body contact region 24 is formed in the active area on the side of the extended gate 212 away from the main gate 211.

In one embodiment, the extended gate 212 extends over the STI structure 28 at both ends. When the main gate 211 and the extended gate 212 make up a T-shaped structure, together with the isolation layer 26 that bridges their projections on the substrate 20, in one embodiment, the main gate 211 may extend, at the end away from the body contact region 24, from the active area over the STI structure 28.

The semiconductor device further includes an interlayer dielectric layer (not shown) covering the main gate 211 and the extended gate 212. The gap between the main gate 211 and the extended gate 212 is filled by the interlayer dielectric layer and the spacer 25. That is, the main gate 211 and the extended gate 212 are insulated from each other by the interlayer dielectric layer and the spacer 25.

The interlayer dielectric layer and the spacer 25 are each made of at least one of silicon oxide, silicon nitride and silicon oxynitride.

The semiconductor device further includes conductive plugs formed on the main gate 211, the source region 22, the drain region 23 and the body contact region 24, but not on the extended gate 212. Through the conductive plugs 27, a voltage can be applied to the main gate 211, the source region 22, the drain region 23 and the body contact region 24, but not to the extended gate 212.

When the main gate 211 and the extended gate 212 make up a T-shaped structure, together with the isolation layer 26 that bridges their projections on the substrate 20, the conductive plugs 27 are preferably formed on the main gate 211 above the STI structure 28. This can ensure reliability and robust performance of the semiconductor device.

Ion implantation for forming the source region 22, the drain region 23 and the body contact region 24 should take into account the critical dimensions (CDs) of the processes used to form the extended gate 212, the body contact region 24, the source region 22 and the drain region 23 and variations in alignment accuracy of photomasks used herein, in order to avoid the resulting source region 22, drain region 23 and body contact region 24 from having undesirable extents. Accordingly, ion implantation for forming the source region 22, the drain region 23 and the body contact region 24 is desired to be performed within areas each extending from over the substrate to over the extended gate 212 (e.g., to the border BB′ of the ion-implanted regions B1 and B2 of FIGS. 2a and 3 to 5). Moreover, a length of the extended gate 212 measured in the direction pointing from the source region 22 to the body contact region 24 (e.g., the gate length L2 of the extended gate 212 measured in the direction pointing from the source region 22 to the body contact region 24 in FIGS. 2a and 3 to 5) should be adequately long (e.g., not less than 0.3μm). On the other hand, if the extended gate 212 is too long, there will be significant parasitic capacitance between the extended gate 212, the gate dielectric layer 201 and the substrate 20, which will degrade the performance of the semiconductor device.

To address this, in the semiconductor device of the present disclosure, the gate layer is designed to consist of the main gate 211 and the extended gate 212, which are separated apart and thus insulated from each other. With this arrangement, a voltage can be applied to the main gate 211, but not to the extended gate 212. Moreover, since the projections of the main gate 211 and the extended gate 212 on the substrate 20 are bridged by the isolation layer 26, the source region 22, the drain region 23 and the body contact region 24 can be formed by ion implantation without connection of the source region 22 and the drain region 23 to each other, or connection of the source region 22 or the drain region 23 to the body contact region 24, which may lead to a short circuit. Further, the isolation layer 26 is formed in the substrate 20, without needing to be controlled to have certain small dimensions. In this way, during the formation of the main gate 211 and the extended gate 212 by etching a gate material layer, since isolation between the main gate 211 and the extended gate 212 is ensured by the isolation layer 26, accurate control of the gap between the main gate 211 and the extended gate 212 is not necessary, simplifying the manufacturing process. This can completely eliminate parasitic capacitance between the extended gate 212, the gate dielectric layer 201 and the substrate 20 while ensuring that the extents of the source region 22, the drain region 23 and the body contact region 24 are as desired and allow the semiconductor device to perform as intended. Thus, the gate layer can function as desired, and performance of the semiconductor device will not be degraded due to the presence of parasitic capacitance. This improves the performance of the semiconductor device, in particular when it is sensitive to gate capacitance (e.g., a low noise amplifier).

In summary, the present disclosure provides a semiconductor device including: a substrate defining an active area; an isolation layer formed in the substrate in the active area; and a gate layer formed over the substrate in the active area. The gate layer includes main gate and the extended gate, which are separated apart from each other, and projections of which on the substrate are bridged by the isolation layer. The semiconductor device can ensure that the gate layer functions as desired while being avoided from any degradation in performance due to parasitic capacitance. Moreover, since the isolation layer is formed in the substrate, accurate control is unnecessary, simplifying the manufacturing process.

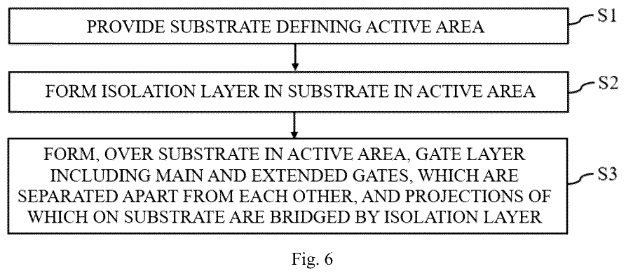

In one embodiment of the present disclosure, there is provided a method of manufacturing a semiconductor device. Reference is now made to FIG. 6, which shows a flowchart of the method. As shown, the method includes the steps of:

Step S1: providing a substrate defining an active area;

Step S2: forming an isolation layer in the substrate in the active area; and

Step S3: forming a gate layer formed over the substrate in the active area. The gate layer includes main gate and the extended gate, which are separated apart from each other, and projections of which on the substrate are bridged by the isolation layer.

A method of manufacturing a semiconductor device according to embodiments of the present disclosure will be described in greater detail below with reference to the schematic top views shown in FIGS. 2a, 3, 4 and 5.

In step S1, a substrate 20 is provided, which defines an active area.

The substrate 20 may be either a single-layer structure, or a multi-layer structure consisting of multiple layers of the same or different materials. Without limitation, examples of the material of the substrate 20 may include semiconductor materials, such as Si, SiGe, SiGeC, SiC, GaAs, InAs, InP and other III/V or II/VI compound semiconductors, or the substrate 20 may be a layered substrate, such as Si/SiGe, Si/SiC, SOI or SiGeOI.

Before a gate layer is subsequently formed in the substrate in the active area 20, the method may further include: forming a STI structure 28 in the substrate 20, which delimits the active area.

Preferably, the isolation layer 26 and the STI structure 28 are formed of the same material in a single process. That is, during the formation of the STI structure 28 in the substrate 20, the isolation layer 26 is formed in the substrate 20 surrounded by the STI structure 28. This can simplify the manufacturing process and reduce the manufacturing cost. In other embodiments, the isolation layer 26 and the STI structure 28 may be formed in different processes.

The isolation layer 26 and the STI structure 28 may each be made of at least one of silicon oxide, silicon nitride and silicon oxynitride.

Preferably, top surfaces of the STI structure 28 and the isolation layer 26 are not lower than a top surface of the substrate 20. In other embodiments, the top surfaces of the STI structure 28 and the isolation layer 26 may be slightly lower than the top surface of the substrate 20.

In step S3, a gate layer is formed over the substrate in the active area 20. The gate layer includes a main gate 211 and an extended gate 212, which are separated apart from each other, and projections of which on the substrate 20 are bridged by the isolation layer 26.

The main gate 211 and the extended gate 212 are spaced apart by a gap, and not electrically connected to, each other.

A gate material layer may be deposited over the substrate 20, the STI structure 28 and the isolation layer 26 and then patterned as desired, thereby forming the gate layer. That is, the gate material layer is separated by etching, thus forming the main gate 211 and the extended gate 212.

Before the gate layer is formed over the substrate 20, a gate dielectric layer 201 may be formed on the substrate in the active area 20. That is, the gate dielectric layer 201 is formed between the gate layer and the substrate 20. The gate layer, the gate dielectric layer 201 and the substrate 20 make up a capacitor structure.

The gate dielectric layer 201 may be made of silicon oxide (with a relative permittivity of 4.1) or another dielectric material. Constructing the gate dielectric layer with a low-k material can reduce the capacitance.

The projections of the main gate 211 and the extended gate 212 on the substrate 20 may overlap the isolation layer 26. That is, borders of the projections of the main gate 211 and the extended gate 212 on the substrate 20 may coincide with borders of the isolation layer 26. In another embodiment, the projections of the main gate 211 and the extended gate 212 on the substrate 20 may extend on portions of the isolation layer 26. With this arrangement, accurate alignment with the borders of the isolation layer 26 is unnecessary during the formation of the main gate 211 and the extended gate 212, enabling easier process control.

Through bridging the projections of the main gate 211 and the extended gate 212 on the substrate 20 with the isolation layer 26, during subsequent formation of a source region 22, a drain region 23 and a body contact region 24 by implanting ions into the active area, the main gate 211, the extended gate 212 and the bridging isolation layer 26 can together serve as a barrier to prevent connection of the source region 22 and the drain region 23 to each other, or connection of the source region 22 or the drain region 23 to the body contact region 24, which may lead to a short circuit.

The method may further include: forming a spacer 25 on sidewalls of the main gate 211 and the extended gate 212.

After the spacer 25 is formed, the method may further include:
forming a source region 22 and a drain region 23 both in the active area on opposite sides of the main gate 211, or of the main gate 211 and the isolation layer 26; and forming a body contact region 24 in the active area on the side of the extended gate 212 and the isolation layer 26 away from the main gate 211.

A region under the main gate 211 between the source region 22 and the drain region 23 provides a channel region. The body contact region 24 is formed to connect the substrate 20 under the channel region (i.e., a body region) to an external circuit. The STI structure 28 surrounds the source region 22, the drain region 23 and the body contact region 24.

In one embodiment, the source region 22 and the drain region 23 may extend to the substrate 20 under the spacer 25. The body contact region 24 may also extend to the substrate 20 under the spacer 25.

The source region 22 and the drain region 23 are of the same doping type, which may be either the same as, or opposite to, that of the body contact region 24. When the doping types of the body contact region 24 and the source region 22 are opposite, the semiconductor device is an enhancement-mode field effect transistor. In case of the body contact region 24 and the source region 22 being of opposite doping types, if the source region 22 and the drain region 23 are n-type regions, then the body contact region 24 is a p-type region. On the contrary, if the source region 22 and the drain region 23 are p-type regions, then the body contact region 24 is an n-type region.

As shown in FIGS. 2a, 3 and 4, the main gate 211 and the extended gate 212 may make up a T-shaped structure, together with the isolation layer 26 that bridges their projections on the substrate 20. In this case, the main gate 211 provides a vertical arm of the T-shaped structure, and the extended gate 212 provides a horizontal arm of the T-shaped structure. Alternatively, as shown in FIG. 5, the main gate 211 and the extended gate 212 may make up an H-shaped structure, together with the isolation layer 26 that bridges their projections on the substrate 20. In this case, the main gate 211 provides a horizontal arm of the H-shaped structure, and the extended gate 212 provides vertical arms of the H-shaped structure.

As long as the isolation layer 26 bridges the projections of the separated main gate and the extended gate 211, 212 on the substrate 20, the present disclosure is not limited to any particular arrangement that accomplishes the bridging. For example, the shapes and dimensions of the isolation layer 26, the main gate 211 and the extended gate 212 may vary depending on the actual processes used.

In one embodiment, as shown in FIGS. 2a, 3 and 5, the extended gate 212 may include a first portion 212a and a second portion 212b, which are separated apart from each other, and projections of which on the substrate 20 are bridged by the isolation layer 26. The projection of the main gate 211 on the substrate 20 may extend from the active area on one side of the isolation layer 26 at least to the isolation layer 26. As shown in FIGS. 2a and 5, the projection of the main gate 211 on the substrate 20 may extend from the active area on one side of the isolation layer 26 just to the isolation layer 26. In this case, the source region 22 and the drain region 23 are formed in the active area on opposite sides of the main gate 211 and the isolation layer 26, and the body contact region 24 is formed in the active area on the side of the extended gate 212 and the isolation layer 26 away from the main gate 211. Alternatively, as shown in FIG. 3, the projection of the main gate 211 on the substrate 20 may extend from the active area on one side of the isolation layer 26 across the entire isolation layer 26 to the active area on the other side of the isolation layer 26. In this case, the source region 22 and the drain region 23 are formed in the active area on opposite sides of the main gate 211, and the body contact region 24 is formed in the active area on the side of the extended gate 212 and the isolation layer 26 away from the source region 22 and the drain region 23. The latter case provides a higher degree of process controllability.

It should be noted that a gate length L2 of the extended gate 212 measured in a direction from the source region 22 to the body contact region 24 does nothing with a length of the isolation layer 26 measured in the same direction.

In an alternative embodiment, as shown in FIG. 4, the extended gate 212 is provided as a single unitary piece. In this case, the source region 22 and the drain region 23 are formed in the active area on opposite sides of the main gate 211 and the isolation layer 26, and the body contact region 24 is formed in the active area on the side of the extended gate 212 away from the main gate 211.

In one embodiment, the extended gate 212 extends over the STI structure 28 at both ends. When the main gate 211 and the extended gate 212 make up a T-shaped structure, together with the isolation layer 26 that bridges their projections on the substrate 20, in one embodiment, the main gate 211 may extend, at the end away from the body contact region 24, from the active area over the STI structure 28.

After the source region 22, the drain region 23 and the body contact region 24 are formed, the method may further include: forming an interlayer dielectric layer (not shown) over the isolation layer 26. The interlayer dielectric layer covers the main gate 211 and the extended gate 212. The gap between the main gate 211 and the extended gate 212 is filled by the interlayer dielectric layer and the spacer 25. That is, the main gate 211 and the extended gate 212 are insulated from each other by the interlayer dielectric layer and the spacer 25.

The interlayer dielectric layer and the spacer 25 are each made of at least one of silicon oxide, silicon nitride and silicon oxynitride.

The method may further include: forming conductive plugs 27 on the main gate 211, the source region 22, the drain region 23 and the body contact region 24, but not on the extended gate 212. Through the conductive plugs 27, a voltage can be applied to the main gate 211, the source region 22, the drain region 23 and the body contact region 24, but not to the extended gate 212.

When the main gate 211 and the extended gate 212 make up a T-shaped structure, together with the isolation layer 26 that bridges their projections on the substrate 20, the conductive plugs 27 are preferably formed on the main gate 211 above the STI structure 28. This can ensure reliability and robust performance of the semiconductor device.

Ion implantation for forming the source region 22, the drain region 23 and the body contact region 24 should take into account the CDs of the processes used to form the extended gate 212, the body contact region 24, the source region 22 and the drain region 23 and variations in alignment accuracy of photomasks used herein, in order to avoid the resulting source region 22, drain region 23 and body contact region 24 from having undesirable extents. Accordingly, ion implantation for forming the source region 22, the drain region 23 and the body contact region 24 is desired to be performed within areas each extending from over the substrate to over the extended gate 212 (e.g., to the border BB′ of the ion-implanted regions B1 and B2 of FIGS. 2a and 3 to 5). Moreover, a length of the extended gate 212 measured in the direction pointing from the source region 22 to the body contact region 24 (e.g., the gate length L2 of the extended gate 212 measured in the direction pointing from the source region 22 to the body contact region 24 in FIGS. 2 a and 3 to 5) should be adequately long (e.g., not less than 0.3μm). On the other hand, if the extended gate 212 is too long, there will be significant parasitic capacitance between the extended gate 212, the gate dielectric layer 201 and the substrate 20, which will degrade the performance of the semiconductor device.

To address this, in the method of the present disclosure, the gate layer is designed to consist of the main gate 211 and the extended gate 212, which are separated apart and thus insulated from each other. With this arrangement, a voltage can be applied to the main gate 211, but not to the extended gate 212. Moreover, since the projections of the main gate 211 and the extended gate 212 on the substrate 20 are bridged by the isolation layer 26, the source region 22, the drain region 23 and the body contact region 24 can be formed by ion implantation without connection of the source region 22 and the drain region 23 to each other, or connection of the source region 22 or the drain region 23 to the body contact region 24, which may lead to a short circuit. Further, the isolation layer 26 is formed in the substrate 20, without needing to be controlled to have certain small dimensions. In this way, during the formation of the main gate 211 and the extended gate 212 by etching a gate material layer, since isolation between the main gate 211 and the extended gate 212 is ensured by the isolation layer 26, accurate control of the gap between the main gate 211 and the extended gate 212 is not necessary, simplifying the manufacturing process. This can completely eliminate parasitic capacitance between the extended gate 212, the gate dielectric layer 201 and the substrate 20 while ensuring that the extents of the source region 22, the drain region 23 and the body contact region 24 are as desired and allow the semiconductor device to perform as intended. Thus, the gate layer can function as desired, and performance of the semiconductor device will not be degraded due to the presence of parasitic capacitance. This improves the performance of the semiconductor device, in particular when it is sensitive to gate capacitance (e.g., a low noise amplifier).

In summary, the present disclosure provides a method of manufacturing a semiconductor device, which includes: providing a substrate defining an active area; forming an isolation layer in the substrate in the active area; and forming a gate layer over the substrate in the active area. The gate layer includes main gate and the extended gate, which are separated apart from each other, and projections of which on the substrate are bridged by the isolation layer. The method can ensure that the gate layer functions as desired while avoiding the resulting semiconductor device from any degradation in performance due to parasitic capacitance. Moreover, since the isolation layer is formed in the substrate, accurate control is unnecessary, simplifying the manufacturing process.

The description presented above is merely that of a few preferred embodiments of the present disclosure and is not intended to limit the scope thereof in any sense. Any and all changes and modifications made by those of ordinary skill in the art based on the above teachings fall within the scope of the disclosure.

What is claimed is:

1. A semiconductor device, comprising:
a substrate defining an active area;
an isolation layer formed in the substrate in the active area; and
a gate layer formed over the substrate in the active area, the gate layer comprising a main gate and an extended gate, the main gate and the extended gate being separated apart from each other, and projections of the main gate and the extended gate on the substrate are bridged by the isolation layer.

2. The semiconductor device of claim 1, wherein the main gate and the extended gate make up a T-shaped structure, together with the isolation layer that bridges the projections of the main gate and the extended gate on the substrate, wherein the main gate provides a vertical arm of the T-shaped structure, and wherein the extended gate provides a horizontal arm of the T-shaped structure.

3. The semiconductor device of claim 1, wherein the main gate and the extended gate make up an H-shaped structure, together with the isolation layer that bridges the projections of the main gate and the extended gate on the substrate, wherein the main gate provides a horizontal arm of the H-shaped structure, and wherein the extended gate provides vertical arms of the H-shaped structure.

4. The semiconductor device of claim 1, wherein the projections of the main gate and the extended gate on the substrate extend on portions of the isolation layer.

5. The semiconductor device of claim 1, further comprising:
a shallow trench isolation structure, which is formed in the substrate, the shallow trench isolation structure being configured to delimit the active area, and wherein the isolation layer and the shallow trench isolation structure are formed of the same material in a same process.

6. The semiconductor device of claim 1, further comprising:
a source region and a drain region, which are formed both in the active area on opposite sides of the main gate, or of the main gate and the isolation layer; and
a body contact region formed in the active area on a side of the extended gate and the isolation layer away from the main gate.

7. The semiconductor device of claim 6, further comprising:
conductive plugs formed on the main gate, the source region, the drain region and the body contact region.

8. The semiconductor device of claim 1, further comprising a gate dielectric layer formed between the gate layer and the substrate.

9. The semiconductor device of claim 1, further comprising a spacer formed on sidewalls of the main gate and the extended gate.

10. The semiconductor device of claim 1, wherein the extended gate comprises a first portion and a second portion, which are separated apart from each other, and projections of the first portion and the second portion on the substrate are bridged by the isolation layer.

11. A method of manufacturing a semiconductor device, comprising:
providing a substrate defining an active area;
forming an isolation layer in the substrate in the active area; and
forming a gate layer over the substrate in the active area, the gate layer comprising a main gate and an extended gate, the main gate and the extended gate being separated apart from each other, and projections of the main gate and the extended gate on the substrate are bridged by the isolation layer.

12. The method of claim 11, wherein the main gate and the extended gate make up a T-shaped structure, together with the isolation layer that bridges the projections of the main gate and the extended gate on the substrate, wherein the main gate provides a vertical arm of the T-shaped structure, and wherein the extended gate provides a horizontal arm of the T-shaped structure.

13. The method of claim 11, wherein the main gate and the extended gate make up an H-shaped structure, together with the isolation layer that bridges the projections of the main gate and the extended gate on the substrate, wherein the main gate provides a horizontal arm of the H-shaped structure, and wherein the extended gate provides vertical arms of the H-shaped structure.

14. The method of claim 11, wherein the projections of the main gate and the extended gate on the substrate extend on portions of the isolation layer.

15. The method of claim 11, further comprising, before the gate layer is formed over the substrate in the active area,
simultaneously forming a shallow trench isolation structure and the isolation layer in the substrate, the shallow trench isolation structure delimiting the active area.

16. The method of claim 11, further comprising:
forming a source region and a drain region both in the active area on opposite sides of the main gate, or of the main gate and the isolation layer; and forming a body contact region in the active area on a side of the extended gate and the isolation layer away from the main gate.

17. The method of claim 16, further comprising:
forming conductive plugs on the main gate, the source region, the drain region and the body contact region.

18. The method of claim 11, before forming the gate layer over the substrate, further comprising forming a gate dielectric layer on the substrate in the active area, the gate dielectric layer formed between the gate layer and the substrate.

19. The method of claim 11, further comprising a spacer formed on sidewalls of the main gate and the extended gate.

20. The method of claim 11, wherein the extended gate comprises a first portion and a second portion, which are separated apart from each other, and projections of the first portion and the second portion on the substrate are bridged by the isolation layer.
